(19) United States
(12) Patent Application Publication
(10) Pub. No.: US 2006/0084239 A1
(43) Pub. Date: Apr. 20, 2006

(54) Wafer dividing method

(75) Inventors: Yusuke Nagai, Tokyo (JP); Kentaro Iizuka, Tokyo (JP)

Correspondence Address: SMITH, GAMBRELL & RUSSELL, LLP, 1850 M STREET, N.W., SUITE 800, WASHINGTON, DC, 20036, US

(73) Assignee: Disco Corporation

(21) Appl. No.: 11/246,103

(22) Filed: Oct. 11, 2005

(30) Foreign Application Priority Data
Oct. 14, 2004 (JP) 2004-300384

(51) Int. Cl. H01L 21/78; H01L 21/301

(52) U.S. Cl. 438/460; 438/462

(57) ABSTRACT

A method of dividing a wafer having a plurality of dividing lines formed in a lattice pattern on the front surface, into individual chips along the dividing lines, the method comprising: a deteriorated layer forming step for forming a deteriorated layer in the inside of the wafer by applying a laser beam capable of passing through the wafer along the dividing lines; a wafer supporting step for putting one surface side of the wafer on a support tape which is mounted on an annular frame and shrinks by an external stimulus; a wafer-dividing step for dividing the wafer along the dividing lines where the deteriorated layer has been formed by exerting external force to the wafer which has been put on the support tape; and a chip spacing formation step for shrinking the shrink area between the inner periphery of the annular frame and the area, to which the wafer is affixed, in the support tape affixed to the divided wafer, by exerting an external stimulus to the shrink area.

### FIELD OF THE INVENTION

The present invention relates to a method of dividing a wafer having a plurality of dividing lines formed on the front surface in a lattice pattern, which has function elements formed thereon in a plurality of areas sectioned by the plurality of dividing lines, into individual chips along the dividing lines.

### DESCRIPTION OF THE PRIOR ART

In the production process of a semiconductor device, a plurality of areas are sectioned by dividing lines called “streets” arranged in a lattice pattern on the front surface of a substantially disk-like semiconductor wafer, and a circuit such as IC or LSI is formed in each of the sectioned areas. Individual semiconductor chips are manufactured by cutting this semiconductor wafer along the dividing lines to divide it into the areas having a circuit formed thereon. An optical device wafer comprising gallium nitride-based compound semiconductors laminated on the front surface of a sapphire substrate is also cut along predetermined dividing lines to be divided into individual optical devices such as light emitting diodes or laser diodes, which are widely used in electric appliances.

Cutting along the dividing lines of the above semiconductor wafer or optical device wafer is generally carried out by using a cutting machine called “dicer”. This cutting machine comprises a chuck table for holding a workpiece such as a semiconductor wafer or optical device wafer, a cutting means for cutting the workpiece held on the chuck table, and a cutting-feed means for moving the chuck table and the cutting means relative to each other. The cutting means comprises a rotary spindle, a cutting blade mounted on the spindle and a drive mechanism for rotary-driving the rotary spindle. The cutting blade comprises a disk-like base and an annular cutting-edge which is mounted on the side wall peripheral portion of the base and formed as thick as about 20 μm by fixing diamond abrasive grains having a diameter of about 3 μm to the base by electroforming.

Since a sapphire substrate, silicon carbide substrate, etc. have high Mohs hardness, however, cutting with the above cutting blade is not always easy. Further, as the cutting blade has a thickness of about 20 μm, the dividing lines for sectioning devices must have a width of about 50 μm. Therefore, in the case of a device measuring 300 μm×300 μm, the area ratio of the streets to the device becomes 14%, thereby reducing productivity.

Meanwhile, as a means of dividing a plate-like workpiece such as a semiconductor wafer, a laser processing method for applying a pulse laser beam having a wavelength capable of passing through the workpiece with its focusing point set to the inside of the area to be divided is also attempted nowadays and disclosed by Japanese Patent No. 3408805. In the dividing method making use of this laser processing technique, the workpiece is divided by applying a pulse laser beam with an infrared range capable of passing through the workpiece with its focusing point set to the inside from one side of the workpiece to continuously form a deteriorated layer in the inside of the workpiece along the dividing lines and exerting external force along the dividing lines whose strength has been reduced by the formation of the deteriorated layers.

As a means of dividing a wafer having deteriorated layers formed continuously along dividing lines into individual chips by exerting external force along the dividing lines of the wafer, the applicant of this application has proposed in JP-A 2005-129607 a technology for dividing the wafer into individual chips along the dividing lines where the deteriorated layer has been formed by expanding a support tape, to which the wafer is affixed, to give tensile force to the wafer.

In the method of dividing the wafer into individual chips by expanding the support tape affixed to the wafer whose strength has been reduced along the dividing lines to give tensile force to the wafer, however, when tensile force is released after the wafer has been divided into individual chips by expanding the support tape, there arises a problem that the expanded support tape shrinks, thereby causing the chips to come into contact with one another during transportation, with the result that the chips are damaged.

### SUMMARY OF THE INVENTION

It is an object of the present invention to provide a method of dividing a wafer having a plurality of dividing lines formed in a lattice pattern on the front surface and function elements formed in a plurality of areas sectioned by the plurality of dividing lines into individual chips along the dividing lines, the individually divided chips being kept apart from one another with a predetermined space.

To attain the above object, according to the present invention, there is provided a method of dividing a wafer having a plurality of dividing lines formed in a lattice pattern on the front surface and function elements formed in a plurality of areas sectioned by the plurality of dividing lines, into individual chips along the dividing lines, the method comprising:
a deteriorated layer forming step for forming a deteriorated layer along the dividing lines in the inside of the wafer by applying a laser beam capable of passing through the wafer along the dividing lines;
a wafer supporting step for putting one surface side of the wafer on the surface of a support tape which is mounted on an annular frame and shrinks by an external stimulus, before or after the deteriorated layer forming step;
a wafer-dividing step for dividing the wafer into individual chips along the dividing lines where the deteriorated layer has been formed by exerting external force to the wafer that has undergone the deteriorated layer forming step and has been put on the support tape; and
a chip spacing formation step for expanding the space between adjacent chips by shrinking a shrink area between the inner periphery of the annular frame and the area, to which the wafer is affixed, in the support tape affixed to the wafer which has undergone the wafer-dividing step, by exerting an external stimulus to the shrink area.

Since the wafer dividing method according to the present invention comprises a chip spacing formation step for expanding the space between adjacent chips by shrinking the shrink area between the inner periphery of the annular frame and the area, to which the wafer is affixed, in the support tape affixed to the wafer divided along the dividing lines where the deteriorated layer has been formed, by exerting an external stimulus to the shrink area of the support tape, the individually divided chips do not come into contact with one another, thereby making it possible to prevent the chips from being damaged by their contact during transportation.

### BRIEF DESCRIPTION OF THE DRAWINGS

FIG. 1 is a perspective view of a semiconductor wafer to be divided into individual chips by the wafer dividing method of the present invention;

FIG. 2 is a perspective view of the principal section of a laser beam processing machine for carrying out the deteriorated layer forming step in the wafer dividing method of the present invention;

FIG. 3 is a block diagram schematically showing the constitution of laser beam application means provided in the laser beam processing machine shown in FIG. 2;

FIG. 4 is a schematic diagram showing the focusing spot diameter of a pulse laser beam;

FIGS. 5(a) and 5(b) are diagrams explaining the deteriorated layer forming step in the wafer dividing method of the present invention;

FIG. 6 is a diagram showing a state where deteriorated layers are laminated in the inside of the wafer in the deteriorated layer forming step shown in FIGS. 5(a) and 5(b);

FIG. 7 is a perspective view showing a state where a semiconductor wafer which has undergone the deteriorated layer forming step has been put on the surface of a support tape affixed to an annular frame;

FIG. 8 is a perspective view of a dividing apparatus for carrying out the wafer-dividing step in the wafer dividing method of the present invention;

FIG. 9 is a sectional view of the dividing apparatus shown in FIG. 8;

FIGS. 10(a) and 10(b) are diagrams showing the wafer-dividing step in the wafer dividing method of the present invention;

FIGS. 11(a) and 11(b) are diagrams showing the chip spacing formation step in the wafer dividing method of the present invention;

FIG. 12 is a diagram showing another embodiment of the wafer-dividing step in the wafer dividing method of the present invention;

FIG. 13 is a diagram showing another embodiment of the chip spacing formation step in the wafer dividing method of the present invention;

FIG. 14 is a diagram showing still another embodiment of the wafer-dividing step in the wafer dividing method of the present invention; and

FIG. 15 is a diagram showing still another embodiment of the chip spacing formation step in the wafer dividing method of the present invention.

### DETAILED DESCRIPTION OF THE PREFERRED EMBODIMENTS

Preferred embodiments of the wafer dividing method of the present invention will be described in detail hereinunder with reference to the accompanying drawings.

FIG. 1 is a perspective view of a semiconductor wafer as a wafer to be divided into individual chips according to the present invention. The semiconductor wafer 10 shown in FIG. 1 is, for example, a silicon wafer having a thickness of 300 μm, and a plurality of dividing lines 101 are formed in a lattice pattern on the front surface 10a. Circuits 102 as function elements are formed in a plurality of areas sectioned by the plurality of dividing lines 101 on the front surface 10a of the semiconductor wafer 10. The method of dividing this semiconductor wafer 10 into individual semiconductor chips will be described hereinunder.

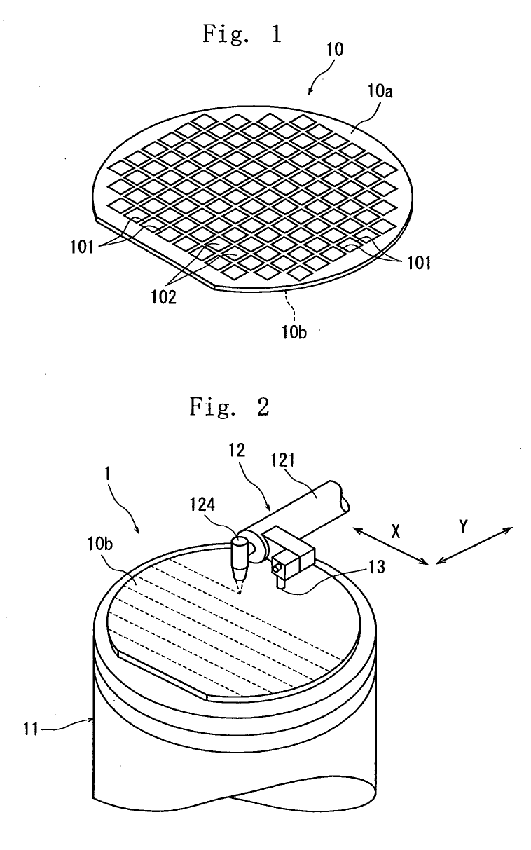

To divide the semiconductor wafer 10 into individual semiconductor chips, a deteriorated layer forming step for forming a deteriorated layer in the inside of the semiconductor wafer 10 along the dividing lines 101 by applying a pulse laser beam of a wavelength capable of passing through the semiconductor wafer 10 along the dividing lines 101 to reduce the strength of the semiconductor wafer 10 along the dividing lines 101 is carried out. This deteriorated layer forming step is carried out by using a laser beam processing machine 1 shown in FIGS. 2 to 4. The laser beam processing machine 1 shown in FIGS. 2 to 4 comprises a chuck table 11 for holding a workpiece, a laser beam application means 12 for applying a laser beam to the workpiece held on the chuck table 11, and an image pick-up means 13 for picking up an image of the workpiece held on the chuck table 11. The chuck table 11 is so constituted as to suction-hold the workpiece, and is designed to be moved in a processing-feed direction indicated by an arrow X and an indexing-feed direction indicated by an arrow Y in FIG. 2 by a moving mechanism that is not shown.

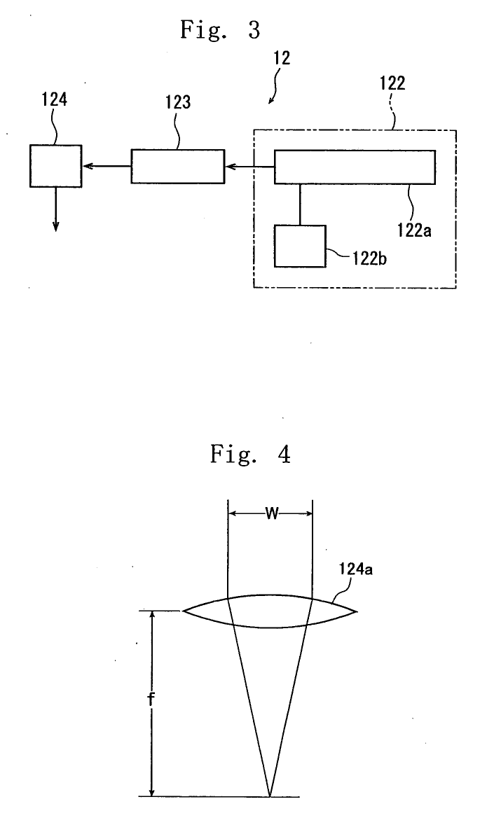

The above laser beam application means 12 has a cylindrical casing 121 arranged substantially horizontally. In the casing 121, as shown in FIG. 3, there are installed a pulse laser beam oscillation means 122 and a transmission optical system 123. The pulse laser beam oscillation means 122 comprises a pulse laser beam oscillator 122a composed of a YAG laser oscillator or YVO4 laser oscillator and a repetition frequency setting means 122b connected to the pulse laser beam oscillator 122a. The transmission optical system 123 comprises suitable optical elements such as a beam splitter, etc. A condenser 124 housing condensing lenses (not shown) constituted by a combination of lenses that may be formation known per se is attached to the end of the above casing 121. A laser beam oscillated from the above pulse laser beam oscillation means 122 reaches the condenser 124 through the transmission optical system 123 and is applied from the condenser 124 to the workpiece held on the above chuck table 11 at a predetermined focusing spot diameter D. This focusing spot diameter D is defined by the expression D (μm)=4×λ×f/(π×W) (wherein λ is the wavelength (μm) of the pulse laser beam, W is the diameter (mm) of the pulse laser beam applied to an objective lens 124a, and f is the focusing distance (mm) of the objective lens 124a) when the pulse laser beam showing a Gaussian distribution is applied through the objective lens 124a of the condenser 124 as shown in FIG. 4.

The image pick-up means 13 attached to the end of the casing 121 constituting the above laser beam application means 12 comprises an infrared illuminating means for applying infrared radiation to the workpiece, an optical system for capturing infrared radiation applied by the infrared illuminating means, and an image pick-up device (infrared CCD) for outputting an electric signal corresponding to infrared radiation captured by the optical system, in addition to an ordinary image pick-up device (CCD) for picking up an image with visible radiation in the illustrated embodiment. An image signal is transmitted to a control means that will be described later.

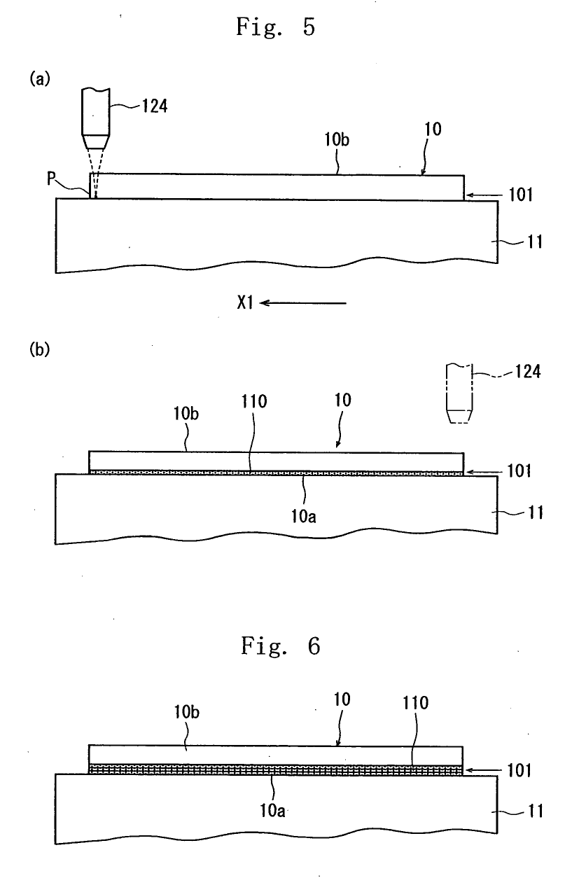

The deteriorated layer forming step which is carried out by using the above laser beam processing machine 1 will be described with reference to FIG. 2, FIGS. 5(a) and 5(b), and FIG. 6.

In this deteriorated layer forming step, the semiconductor wafer 10 is first placed on the chuck table 11 of the laser beam processing machine 1 shown in FIG. 2 in such a manner that the back surface 10b faces up, and is suction-held on the chuck table 11. The chuck table 11 suction-holding the semiconductor wafer 10 is positioned right below the image pick-up means 13 by a moving mechanism that is not shown.

After the chuck table 11 is positioned right below the image pick-up means 13, alignment work for detecting the area to be processed of the semiconductor wafer 10 is carried out by using the image pick-up means 13 and the control means that is not shown. That is, the image pick-up means 13 and the control means (not shown) carry out image processing such as pattern matching to align a dividing line 101 formed in a predetermined direction of the semiconductor wafer 10 with the condenser 124 of the laser beam application means 12 for applying a laser beam along the dividing line 101, thereby performing the alignment of a laser beam application position. The alignment of the laser beam application position is also carried out on dividing lines 101 formed on the semiconductor wafer 10 in a direction perpendicular to the predetermined direction. Although the front surface 10a having the dividing lines 101 formed thereon of the semiconductor wafer 10 faces down at this point, as the image pick-up means 13 comprises an infrared illuminating means, an optical system for capturing infrared radiation and an image pick-up device (infrared CCD) for outputting an electric signal corresponding to the infrared radiation as described above, an image of the dividing line 101 can be picked up through the back surface 10b.

After the dividing line 101 formed on the semiconductor wafer 10 held on the chuck table 11 is detected and the alignment of the laser beam application position is carried out as described above, the chuck table 11 is moved to a laser beam application area where the condenser 124 of the laser beam application means 12 for applying a laser beam is located as shown in FIG. 5(a) to bring one end (left end in FIG. 5(a)) of the predetermined dividing line 101 to a position right below the condenser 124 of the laser beam application means 12, as shown in FIG. 5(a). The chuck table 11, that is, the semiconductor wafer 10 is then moved in the direction indicated by the arrow X1 in FIG. 5(a) at a predetermined processing-feed rate while the pulse laser beam of a wavelength capable of passing through the semiconductor wafer 10 is applied from the condenser 124. When the application position of the condenser 124 of the laser beam application means 12 reaches the other end (right end in FIG. 5(b)) of the dividing line 101 as shown in FIG. 5(b), the application of the pulse laser beam is suspended and the movement of the chuck table 11, that is, the semiconductor wafer 10 is stopped. In this deteriorated layer forming step, the focusing point P of the pulse laser beam is set to a position near the front surface 10a (undersurface) of the semiconductor wafer 10. As a result, a deteriorated layer 110 is exposed to the front surface 10a (undersurface) and formed from the front surface 10a (undersurface) toward the inside. This deteriorated layer 110 is formed as a molten and re-solidified layer (that is, the deteriorated layer has been once molten and then, re-solidified.).

The processing conditions in the above deteriorated layer forming step are set as follows, for example.
Light source: LD excited Q switch Nd:YVO4 laser
Wavelength: pulse laser beam having a wavelength of 1,064 nm
Pulse output: 10 μJ
Focusing spot diameter: 1 μm
Repetition frequency: 100 kHz
Processing-feed rate: 100 mm/sec

When the semiconductor wafer 10 is thick, as shown in FIG. 6, the above deteriorated layer forming step is carried out a plurality of times by changing the focusing point P stepwise to form a plurality of deteriorated layers 110. For example, since the thickness of the deteriorated layer formed each time under the above processing conditions is about 50 μm, the above deteriorated layer forming step is carried out 3 times to form deteriorated layers 110 having a total thickness of 150 μm. In the case of a wafer 10 having a thickness of 300 μm, six deteriorated layers may be formed along the dividing lines 101 from the front surface 10a to the back surface 10b in the inside of the semiconductor wafer 10.

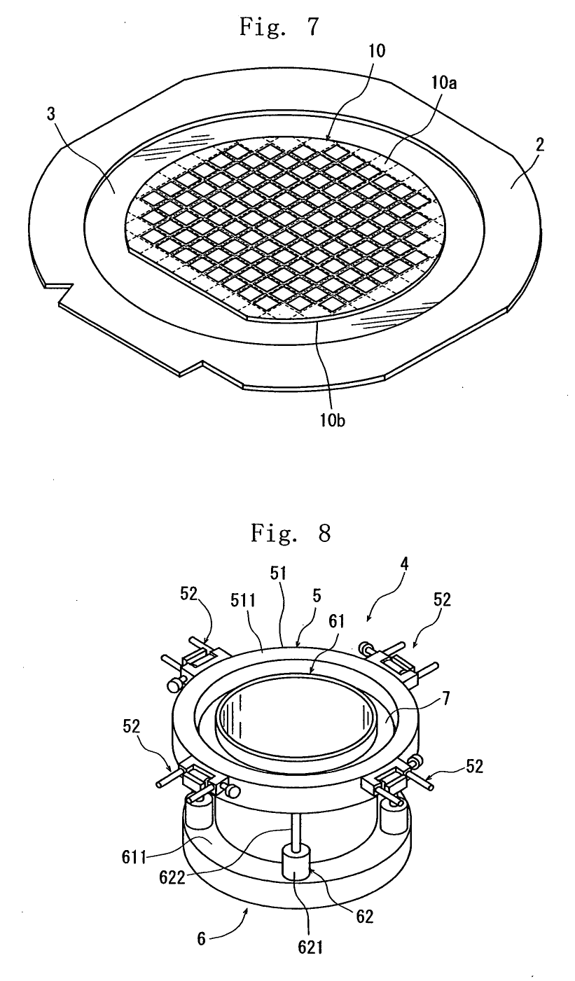

After the deteriorated layer 110 is formed along all the dividing lines 101 in the inside of the semiconductor wafer 10 by the above-described deteriorated layer forming step, a wafer supporting step for putting one surface side of the wafer onto the surface of a support tape, which is mounted on an annular frame and shrinks by an external stimulus, is carried out. That is, as shown in FIG. 7, the back surface 10b of the semiconductor wafer 10 is put on the surface of the support tape 3 whose peripheral portion is mounted on the annular frame 2 so as to cover its inner opening. The above support tape 3 is prepared by coating an about 5 μm-thick acrylic resin-based adhesive layer on the surface of a 70 μm-thick sheet backing made of polyvinyl chloride (PVC) in the illustrated embodiment. The sheet backing of the support tape 3 is desirably a sheet of a synthetic resin such as polyvinyl chloride (PVC), polypropylene, polyethylene or polyolefin which is shrinkable at normal temperature and has a property that it shrinks by heat at a predetermined temperature (for example, 70° C.) or higher. As the above support tape may be used a sheet disclosed by JP-A 2004-119992, for example.

The above-described wafer supporting step may be carried out before the above deteriorated layer forming step. In this case, the front surface 10a of the semiconductor wafer 10 is put on the surface of the above support tape 3 mounted on the annular frame 2 (therefore, the back surface 10b of the semiconductor wafer 10 faces up). Then, the above deteriorated layer forming step is carried out in a state where the semiconductor wafer 10 is put on the above support tape 3 mounted on the annular frame 2.

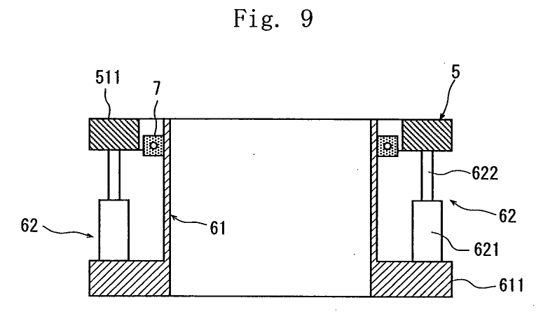

After the above-described deteriorated layer forming step and wafer supporting step, next comes the wafer-dividing step for dividing the semiconductor wafer 10 into individual chips along the dividing lines 101 where the above deteriorated layer 110 has been formed by exerting external force to the semiconductor wafer 10 put on the support tape 3 mounted on the annular frame 2. This wafer-dividing step is carried out by using a dividing apparatus 4 shown in FIGS. 8 and 9.

FIG. 8 is a perspective view of the dividing apparatus 4, and FIG. 9 is a sectional view of the dividing apparatus 4 shown in FIG. 8. The dividing apparatus 4 in the illustrated embodiment has a frame holding means 5 for holding the above annular frame 2 and a tension exerting means 6 for expanding the support tape 3 mounted on the above annular frame 2. The frame holding means 5 comprises an annular frame holding member 51 and four clamps 52 as a fixing means arranged around the frame holding member 51 as shown in FIG. 8 and FIG. 9. The top surface of the frame holding member 51 forms a placing surface 511 for placing the annular frame 2, and the annular frame 2 is placed on this placing surface 511. The annular frame 2 placed on the placing surface 511 of the frame holding member 51 is fixed on the frame holding member 51 by the clamps 52.

The above tension exerting means 6 comprises an expansion drum 61 arranged within the above annular frame holding member 51. This expansion drum 61 has a smaller inner diameter than the inner diameter of the annular frame 2 and a larger outer diameter than the outer diameter of the semiconductor wafer 10 put on the support tape 3 mounted on the annular frame 2. The expansion drum 61 has a support flange 611 at the lower end. The tension exerting means 6 in the illustrated embodiment comprises a support means 62 capable of moving the above annular frame holding member 51 in the vertical direction (axial direction). This support means 63 comprises a plurality (4 in the illustrated embodiment) of air cylinders 621 installed on the above support flange 611, and their piston rods 622 are connected to the undersurface of the above annular frame holding member 51. The support means 62 comprising the plurality of air cylinders 621 as described above moves the annular frame holding member 51 in the up-and-down direction between a standard position where the placing surface 511 becomes substantially the same in height as the upper end of the expansion drum 61 and an expansion position where the placing surface 511 is positioned below the upper end of the expansion drum 61 by a predetermined distance.

The illustrated dividing apparatus 4 comprises an annular infrared heater 7 as an external stimulus application means mounted on the outer peripheral surface of the upper portion of the above expansion drum 61. This infrared heater 7 heats the area between the inner periphery of the annular frame 2 and the semiconductor wafer 10 in the support tape 3 mounted on the annular frame 2 held on the above frame holding means 5.

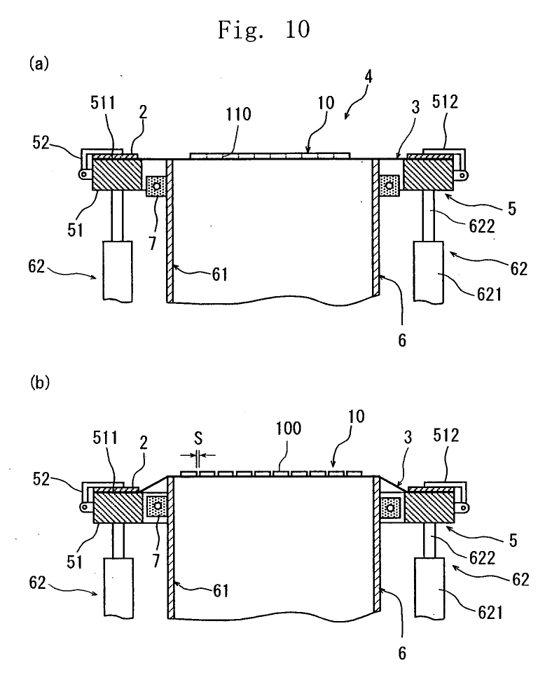

The wafer-dividing step which is carried out by using the above constituted dividing apparatus 4 will be described with reference to FIGS. 10(a) and 10(b). That is, the annular frame 2 supporting the semiconductor wafer 10 (in which the deteriorated layer 110 is formed along the dividing lines 101) through the support tape 3 as shown in FIG. 7 is placed on the placing surface 511 of the frame holding member 51 constituting the frame holding means 5 and fixed on the frame holding member 51 by the clamps 52, as shown in FIG. 10(a). At this point, the frame holding member 51 is situated at the standard position shown in FIG. 10(a).

Thereafter, the annular frame holding member 51 is lowered to the expansion position shown in FIG. 10(b) by activating the plurality of air cylinders 621 as the support means 62 constituting the tension exerting means 6. Therefore, the annular frame 2 fixed on the placing surface 511 of the frame holding member 51 is also lowered, whereby the support tape 3 mounted on the annular frame 2 comes into contact with the upper edge of the expansion drum 61 to be expanded, as shown in FIG. 10(b). As a result, tensile force acts radially on the semiconductor wafer 10 put on the support tape 3, thereby dividing the semiconductor wafer 10 into individual semiconductor chips 100 along the dividing lines 101 whose strength has been reduced by the formation of the deteriorated layers 110. Since the support tape 3 is expanded in this tape expanding step as described above, when the semiconductor wafer 10 is divided into individual semiconductor chips 100, a space S is formed between adjacent chips. The expansion or elongation quantity of the support tape 3 in the above tape expanding step can be adjusted by the downward movement amount of the frame holding member 51. According to experiments conducted by the inventors of the present invention, when the support tape 3 was stretched about 20 mm, the semiconductor wafer 10 could be divided along the dividing lines 101 where the deteriorated layer 110 was formed. The space S between adjacent semiconductor chips 100 was about 1 mm.

When the expansion of the support tape 3 by the tension exerting means 6 is cancelled after the above wafer-dividing step, the support tape 3 shrinks and returns to the state shown in FIG. 7 before tensile force is exerted, and the space S between the semiconductor chips 100 becomes substantially nil.

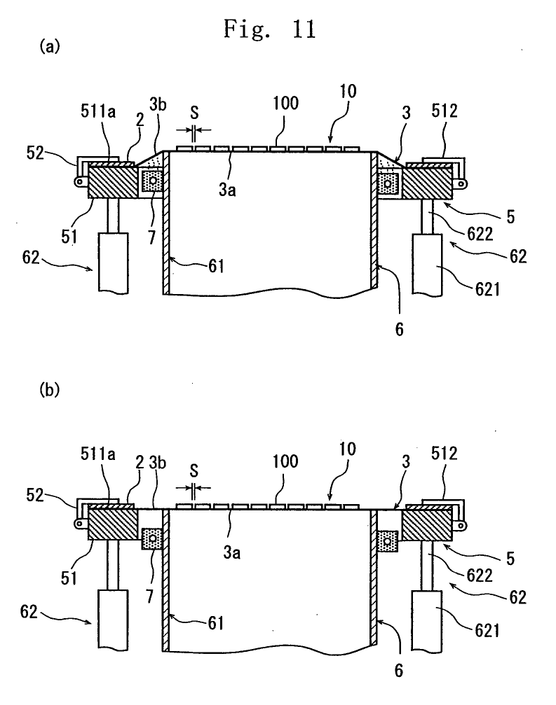

Accordingly, in the present invention, the chip spacing formation step for shrinking the shrink area of the support tape by exerting an external stimulus to the shrink area between the inner periphery of the annular frame and the area, to which the wafer is affixed, in the support tape affixed to the wafer which has undergone the wafer-dividing step is carried out to expand the space between adjacent chips. In this chip spacing formation step, the infrared heater 7 is turned on in a state where the above wafer-dividing step has been carried out as shown in FIG. 11(a). As a result, the shrink area 3b between the inner periphery of the annular frame 2 and the area 3a, to which the semiconductor wafer 10 is affixed, of the support tape 3 is shrunk by heating with infrared radiation applied by the infrared heater 7. Along with this shrinking function, the annular frame holding member 51 is moved up to the standard position shown in FIG. 11(b) by activating the plurality of air cylinders 621 as the support means 62 constituting the tension exerting means 6. The temperature for heating the support tape 3 by the above infrared heater 7 is suitably 70 to 100° C. and the heating time is 5 to 10 seconds. By shrinking the shrink area 3b between the inner periphery of the annular frame 2 and the area 3a, to which the semiconductor wafer 10 is affixed, of the support tape 3 as described above, the space S between semiconductor chips 100, which have been separated from one another in the above wafer-dividing step, is maintained. Therefore, the obtained semiconductor chips 100 do not come into contact with one another, thereby making it possible to prevent the semiconductor chips 100 from being damaged by their contact during transportation or the like.

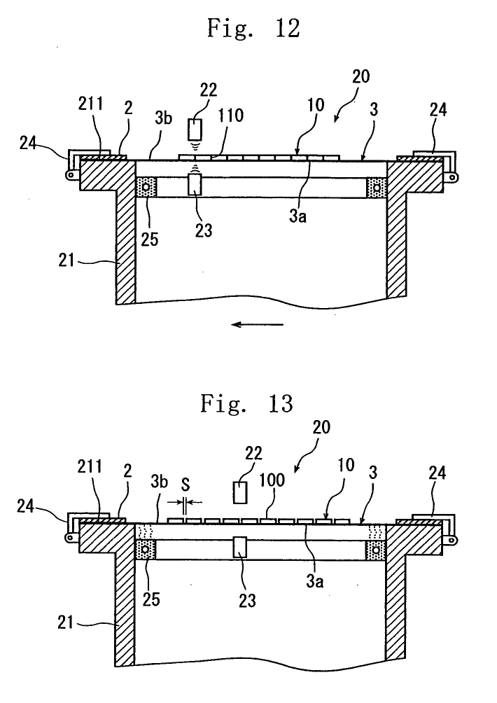

A description will be subsequently given of the wafer-dividing step and the chip spacing formation step in another embodiment of the wafer dividing method of the present invention with reference to FIG. 12 and FIG. 13.

In this embodiment, an ultrasonic dividing apparatus 20 is used. The ultrasonic dividing apparatus 20 comprises a cylindrical frame holding member 21, a first ultrasonic oscillator 22 and a second ultrasonic oscillator 23. The cylindrical frame holding member 21 constituting the ultrasonic dividing apparatus 20 has a top surface as a placing surface 211 for placing the above annular frame, and the above annular frame 2 is placed on the placing surface 211 and fixed by clamps 24. This frame holding member 21 is so constituted as to be moved in a horizontal direction and a direction perpendicular to the sheet in FIG. 12 and as to be turned by a moving means that is not shown. The first ultrasonic oscillator 22 and the second ultrasonic oscillator 23 constituting the ultrasonic dividing apparatus 20 are arranged, opposed to each other, in such a manner that the semiconductor wafer 2 supported to the annular frame 2 placed on the placing surface 211 of the cylindrical frame holding member 21 through the support tape 3 is interposed between them, and generate longitudinal waves (compressional waves) having a predetermined frequency. The ultrasonic dividing apparatus 20 in the illustrated embodiment comprises an annular infrared heater 25 as an external stimulus exerting means installed on the inner peripheral surface of the upper portion of the frame holding member 21. This infrared heater 25 heats the shrink area 3b between the inner periphery of the annular frame 2 and the area 3a, to which the semiconductor wafer 10 is affixed, of the support tape 3 mounted on the annular frame 2 held on the above frame holding member 21.

To carry out the wafer-dividing step by using the thus constituted ultrasonic dividing apparatus 20, the annular frame 2 supporting the semiconductor wafer 10 (in which the deteriorated layer 110 is formed along the dividing lines 101) through the support tape 3 is placed on the placing surface 211 of the cylindrical frame holding member 21 in such a manner that the support tape 3 side, onto which the semiconductor wafer 10 is mounted, faces down (therefore, the front surface 10a of the semiconductor wafer 10 faces up) and is fixed by the clamps 24. Thereafter, the frame holding member 21 is moved by the moving means (not shown) to bring one end (left end in FIG. 12) of a predetermined dividing line 101 formed on the semiconductor wafer 10 to a position where ultrasonic waves from the first ultrasonic oscillator 22 and the second ultrasonic oscillator 23 act thereon. The first ultrasonic oscillator 22 and the second ultrasonic oscillator 23 are then activated to generate longitudinal waves (compressional waves) having a frequency of 28 kHz, for example, and at the same time, the frame holding member 21 is moved in the direction indicated by the arrow at a feed rate of 50 to 100 mm/sec. As a result, the ultrasonic waves generated from the first ultrasonic oscillator 22 and the second ultrasonic oscillator 23 act on the front surface 10a and back surface 10b of the semiconductor wafer 10 along the dividing line 101, whereby the semiconductor wafer 10 is divided along the dividing line 101 whose strength has been reduced by the formation of the deteriorated layer 110. After the wafer-dividing step is carried out along the predetermined dividing line 101 as described above, the frame holding member 21 is index-fed by a distance corresponding to the interval between the dividing lines 101 in the direction perpendicular to the sheet to carry out the above wafer-dividing step. After the above wafer-dividing step is carried out along all the dividing lines 21 formed in the predetermined direction, the frame holding member 21 is turned at 90° to carry out the above wafer-dividing step along dividing lines 101 formed in a direction perpendicular to the above predetermined direction, whereby the semiconductor wafer 10 is divided into individual chips along the dividing lines 101 formed in a lattice pattern. Since the back surfaces of the individually divided chips stick to the support tape 3, they do not fall apart and hence, the state of the wafer is maintained.

After the above wafer-dividing step as described above, next comes the chip spacing formation step. That is, as shown in FIG. 13, the infrared heater 25 is turned on. As a result, the shrink area 3b between the inner periphery of the annular frame 2 and the area 3a, to which the semiconductor wafer 10 is affixed, of the support tape 3 is shrunk by heating with infrared radiation applied by the infrared heater 25. Thus, the shrink area 3b between the inner periphery of the annular frame 2 and the area 3a, to which the semiconductor wafer 10 is affixed, of the support tape 3 is shrunk to expand the space between adjacent individually divided semiconductor chips, thereby maintaining the space S. Therefore, the individually divided semiconductor chips 100 do not come into contact with one another, thereby making it possible to prevent the semiconductor chips from being damaged by their contact during transportation or the like.

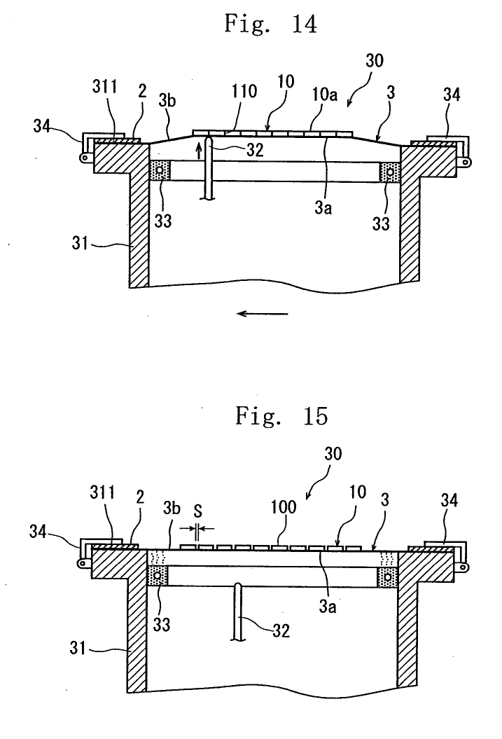

A description will be subsequently given of the wafer-dividing step and the chip spacing formation step in still another embodiment of the wafer dividing method of the present invention with reference to FIG. 14 and FIG. 15.

In this embodiment, a bending dividing apparatus 30 comprising a cylindrical frame holding member 31 and a pressing member 32 as a bending-load application means is used. This frame holding member 31 is so constituted as to be moved in the horizontal direction and the direction perpendicular to the sheet in FIG. 14 and as to be turned by a moving means that is not shown. The bending dividing apparatus 3 in the illustrated embodiment comprises an annular infrared heater 33 as an external stimulus exerting means installed on the inner peripheral surface of the upper portion of the frame holding member 31. This infrared heater 33 heats the shrink area 3b between the inner periphery of the annular frame 2 and the area 3a, to which the semiconductor wafer 10 is affixed, in the support tape 3 mounted on the annular frame 2 held on the above frame holding member 31.

To carry out the wafer-dividing step by using the thus constituted bending dividing apparatus 30, the annular frame 2 supporting the semiconductor wafer 10 (in which the deteriorated layer 110 is formed along the dividing lines 101) through the support tape 3 is placed on the placing surface 311 of the frame holding member 31 in such a manner that the support tape 3 side, onto which the semiconductor wafer 10 is mounted, faces down (therefore, the front surface 10a of the semiconductor wafer 10 faces up) and is fixed by clamps 34. Thereafter, the frame holding member 31 is moved by the moving means (not shown) to bring one end (left end in FIG. 14) of a predetermined dividing line 101 formed on the semiconductor wafer 10 to a position where it is opposed to the pressing member 32 and the pressing member 32 is moved up in FIG. 14 to press the support tape 3 affixed to the semiconductor wafer 10. The frame holding member 31 is then moved in the direction indicated by the arrow. As a result, a bending load acts on the semiconductor wafer 10 along the dividing line pressed by the pressing member 32 to generate tensile stress on the front surface 10a, whereby the semiconductor wafer 10 is divided along the dividing line 101 whose strength has been reduced by the formation of the deteriorated layer 110. After the dividing step is thus carried out along the predetermined dividing line 101, the frame holding member 31 is index-fed by a distance corresponding to the interval between the dividing lines 101 in the direction perpendicular to the sheet to carry out the above wafer-dividing step. After the wafer-dividing step is carried out along all the dividing lines extending in the predetermined direction, the frame holding member 31 is turned at 90° to carry out the above wafer-dividing step along dividing lines 101 formed in a direction perpendicular to the predetermined direction, whereby the semiconductor wafer 10 is divided into individual chips. Since the back surfaces of the individually divided chips 100 stick to the support tape 3, they do not fall apart and hence, the state of the wafer is maintained.

After the wafer-dividing step is carried out as described above, next comes the chip spacing formation step. That is, as shown in FIG. 15, the infrared heater 33 is turned on. As a result, the shrink area 3b between the inner periphery of the annular frame 2 and the area 3a, on which the semiconductor wafer 10 is affixed, of the support tape 3 is shrunk by heating with infrared radiation applied by the infrared heater 33. By shrinking the shrink area 3b between the inner periphery of the annular frame 2 and the area 3a, on which the semiconductor wafer 10 is affixed, of the support tape 3, the space between adjacent individually divided semiconductor chips 100 is expanded and the space S is maintained. Therefore, the individually divided semiconductor chips 100 do not come into contact with one another, thereby making it possible to prevent the semiconductor chips 100 from being damaged by their contact during transportation or the like.

What is claimed is:

1. A method of dividing a wafer having a plurality of dividing lines formed in a lattice pattern on the front surface and function elements formed in a plurality of areas sectioned by the plurality of dividing lines, into individual chips along the dividing lines, the method comprising:
a deteriorated layer forming step for forming a deteriorated layer along the dividing lines in the inside of the wafer by applying a laser beam capable of passing through the wafer along the dividing lines;
a wafer supporting step for putting one surface side of the wafer on the surface of a support tape which is mounted on an annular frame and shrinks by an external stimulus, before or after the deteriorated layer forming step;
a wafer-dividing step for dividing the wafer into individual chips along the dividing lines where the deteriorated layer has been formed by exerting external force to the wafer that has undergone the deteriorated layer forming step and has been put on the support tape; and
a chip spacing formation step for expanding the space between adjacent chips by shrinking a shrink area between the inner periphery of the annular frame and the area, to which the wafer is affixed, in the support tape affixed to the wafer which has undergone the wafer-dividing step, by exerting an external stimulus to the shrink area.
